(19) United States
(12) Patent Application Publication
(10) Pub. No.: US 2011/0018555 A1
(43) Pub. Date: Jan. 27, 2011

(54) Electrical Measuring Device, Method and Computer Program Product

(75) Inventors: Gerardus Cornelis Maria Meijer, Delft (NL); Maximus Andreas Hilhorst, Lunteren (NL)

Correspondence Address: SWANSON & BRATSCHUN, L.L.C., 8210 SOUTHPARK TERRACE, LITTLETON, CO, 80120, US

(73) Assignee: Technische Universiteit Delft, BL Delft (NL)

(21) Appl. No.: 12/521,539

(22) PCT Filed: Jan. 2, 2008
(86) PCT No.: PCT/NL08/50002

§ 371 Date: Sep. 18, 2009

(30) Foreign Application Priority Data
Dec. 29, 2006 (NL) 1033148

(51) Int. Cl. G01R 27/28

(52) U.S. Cl. 324/652

(57) ABSTRACT

The invention relates to an electrical measuring device for performing an electrical impedance measurement in a contactless manner. The measuring device comprises a measuring unit which is provided with the impedance to be measured and a passive resonance circuit connected thereto for generating a measuring signal to be wirelessly received by a separate active transmitting and receiving unit for determination of the electrical impedance, upon wireless reception of an interrogation signal transmitted by the active transmitting and receiving unit. Further, the measuring unit is provided with an additional reference circuit which is preferably connected to the resonance circuit for, depending upon the interrogation signal, generating a reference signal to be received by the active transmitting and receiving unit.

The invention relates to an electrical measuring device for performing an electrical impedance measurement, comprising a measuring unit which is provided with the impedance to be measured and a passive resonance circuit connected thereto for generating a measuring signal to be received by a separate active transmitting and receiving unit for determination of the electrical impedance upon reception of an interrogation signal transmitted by the active transmitting and receiving unit.

U.S. Pat. No. 6,870,376 describes an electrical measuring device for performing an electrical impedance measurement for the purpose of determining the humidity level in, for instance, the soil or the substrate in which a plant is rooted. The impedance is basically a capacitor that varies depending on the humidity near the capacitor. Thus, in an electrical manner, the humidity level can be locally determined.

Further known, for instance from the scientific article “Remote Query Resonant-Circuit Sensors for Monitoring of Bacteria Growth: Application to Food Quality Control” by Keat Ghee Ong and others, published in Sensors, pp. 219-232, 2002, is an electrical measuring device according to the opening paragraph hereof, where an impedance designed as a capacitor is part of a passive resonance circuit of a measuring unit which is galvanically decoupled from an element of a separate transmitting and receiving unit that transmits and receives electromagnetic fields. By electromagnetically coupling the transmitting and receiving unit to the resonance circuit, information about the capacitor can be gained, since capacitive values of the capacitor—which in their turn are dependent upon for instance a local humidity level—affect the behavior of the resonance circuit. The measuring device can be employed for checking for instance bacterial growth in foods.

During operation of the measuring device, the transmitting and receiving unit transmits an electromagnetic interrogation signal, whereupon the passive resonance circuit generates a reflective measuring signal which is thereupon received and analyzed by the separate transmitting and receiving unit. Depending on actual values of the capacitor, the peak frequency of the measuring signal can vary, so that a measure is obtained for the humidity adjacent the capacitor in the measuring unit.

Advantages of such a contactless impedance measurement are inter alia low manufacturing costs per measuring unit and a relatively long life because of the use of passive components, and ease of use in performing the measurement, since the user hardly if at all needs to perform any mechanical operations which are time consuming and tend to lead to measuring errors, such as placing a measuring unit in a sample and removing the measuring unit from the sample.

For obtaining a qualitatively good contactless impedance measurement, the measuring unit is calibrated using a reference measurement, where the impedance is situated in a conditioned space. Such a reference measurement is performed prior to in situ placement of the measuring unit.

This involves the problem that upon placement of the measuring unit, practically no reference measurement is possible anymore, while yet parameters of the resonance circuit may drift, for instance through ageing. This renders the impedance measurement less pure. In addition, carrying out the reference measurement is experienced as user unfriendly and labor intensive.

The object of the invention is to provide an electrical measuring device according to the opening paragraph hereof, whereby, whilst maintaining the advantages, the disadvantages mentioned are obviated. In particular, the object of the invention is to provide an electrical measuring device according to the opening paragraph hereof whereby the accuracy of the impedance measurement is augmented. To that end, the measuring unit is furthermore arranged for, depending upon the interrogation signal, generating with the aid of the resonance circuit a reference signal to be received by the active transmitting and receiving unit.

By providing a measuring device whereby during a reference measurement, depending upon the interrogation signal, with the aid of the resonance circuit a reference signal to be received by the active transmitting and receiving unit is generated, the reference measurement can advantageously take place at any location and time, also there where the impedance measurement is to be carried out. On the basis of the reference measurement, which can thus be carried out according to need and as often as desired, the impedance can be calibrated, so that the accuracy of the impedance measurement augments.

Moreover, correction for drifting parameters of the resonance circuit is enabled. In addition, the reference measurement where the measuring unit is placed in a conditioned space, has become redundant, which enhances ease of use and reduces extra costs in placing the measuring unit to a large extent. Also, manufacturing tolerances in respect of elements in the resonance circuit may be less stringent, which contributes to a further cost price decrease.

When a single transmitting and receiving unit is used in combination with a plurality of measuring units, this entails a cost advantage since the measuring unit can consist of relatively few, inexpensive components, while relatively complex electronics for analyzing the measuring and reference signals can be implemented in the transmitting and receiving unit.

In addition, elegantly, components are saved on by transmitting both the measuring signal and the reference signal with the aid of the resonance circuit.

It is noted that the term impedance may be understood to cover a variety of types of passive discrete electrical elements, as a capacitor, inductor and/or resistor, as well as materials displaying a capacitive, inductive and/or resistive behavior. In this connection, also terms such as dielectric behavior or the conductivity of a material are customary. The technique of measuring an electrical impedance as a measure for a physical change is sometimes designated as impedance spectroscopy.

The reference signal is generated depending upon the interrogation signal. The nature of this dependency may be implemented in various ways. Thus, for instance, the frequency and/or amplitude of the interrogation signal may vary to cause, as desired, a measuring signal or a reference signal to be generated. Also, the interrogation signal may be provided with a code for generating a measuring signal or a reference signal. For that matter, it may also be elected to design the interrogation signal such that both the measuring signal and the reference signal are generated.

Preferably, the signals transmitted by the measuring unit are narrow-band. The measuring signal and the single or multiple reference signals are then situated in a limited bandwidth, so that in practice the electrical measuring device can be used in an available frequency band. Thus, the frequencies of the measuring signal and of the single or multiple reference signals may for instance differ from each other by a few percents or less.

Advantageously, the measuring unit may be arranged for, depending upon the interrogation signal, generating with the aid of the resonance circuit a specific reference signal from a plurality of reference signals. By enabling transmission of a plurality of reference signals, more information of the measuring system can become available at the separate transmitting and receiving unit, for instance for improving the measurement or for obtaining other information about the measuring unit, such as identification information of the measuring unit.

According to an aspect of the invention, the measuring unit and the separate active transmitting and receiving unit are arranged for wireless mutual signal transfer, thus allowing a contactless measurement. As a result, the ease of use of the electrical measuring device increases, since no wire connections are needed then for establishing signal transfer between the separate active transmitting and receiving unit and the measuring unit. Alternatively, however, signal transfer can also be effected with the aid of a wire connection, for instance to realize a saving of costs or to improve the reliability and/or sensitivity of the signal transfer.

According to an aspect of the invention, the measuring unit can furthermore comprise a reference circuit for, depending upon the interrogation signal, generating with the aid of the resonance circuit a reference signal. By influencing the amplitude characteristic in a controlled manner in this way, an absolute calibration can be carried out with the extra measurement.

According to another aspect of the invention, the electrical properties of the resonance circuit remain invariant, while the measuring unit is furthermore arranged for, depending upon the interrogation signal, generating with the aid of the resonance circuit a reference signal having a central frequency that differs from the central frequency of the measuring signal. In this way, extra information about the characteristic becomes available, so that likewise an absolute calibration can be carried out.

By connecting the additional reference circuit to the resonance circuit, the circuit can be employed for generating both the measuring signal and the reference signal, so that the number of electrical components of the measuring unit may be saved on. Alternatively, however, the additional reference circuit may also be part of a separate resonance circuit, so that measuring signal and reference signal are generated separately.

By connecting the impedance to be measured or the additional reference circuit to the resonance circuit via a switching element, a measuring or reference signal may be generated depending upon the state of the switching element. The state of the switching element can be influenced by the interrogation signal for obtaining the desired signal.

The additional reference circuit may be placed in a space which is at least partially conditioned, preferably in such a manner that the electrical properties of the reference circuit are substantially invariant compared with corresponding property variations of the impedance to be measured, so as to obtain a meaningful reference measurement.

By making the additional reference circuit of passive design, the circuit of the measuring unit can be manufactured particularly cheaply, while the operational life is practically unlimited. However, the additional reference circuit may also be designed with a compact energy source, so that a simplification in the complexity of the signal to be analyzed may be achieved.

Furthermore, the invention relates to a method.

Also, the invention relates to a computer program product.

Further advantageous embodiments of the invention are represented in the subclaims.

The invention will be further elucidated on the basis of exemplary embodiments which are represented in the drawing. In the drawing:

FIG. 1 shows a circuit of a first embodiment of an electrical measuring device according to the invention;

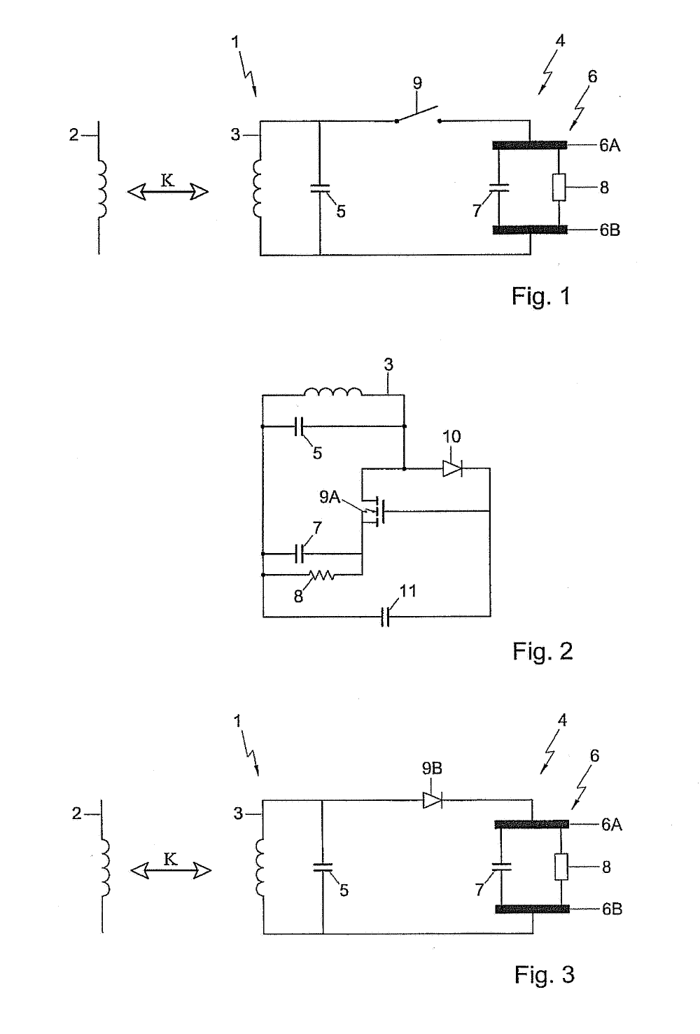

FIG. 2 shows a circuit of a second embodiment of an electrical measuring device according to the invention;

FIG. 3 shows a circuit of a third embodiment of an electrical measuring device according to the invention;

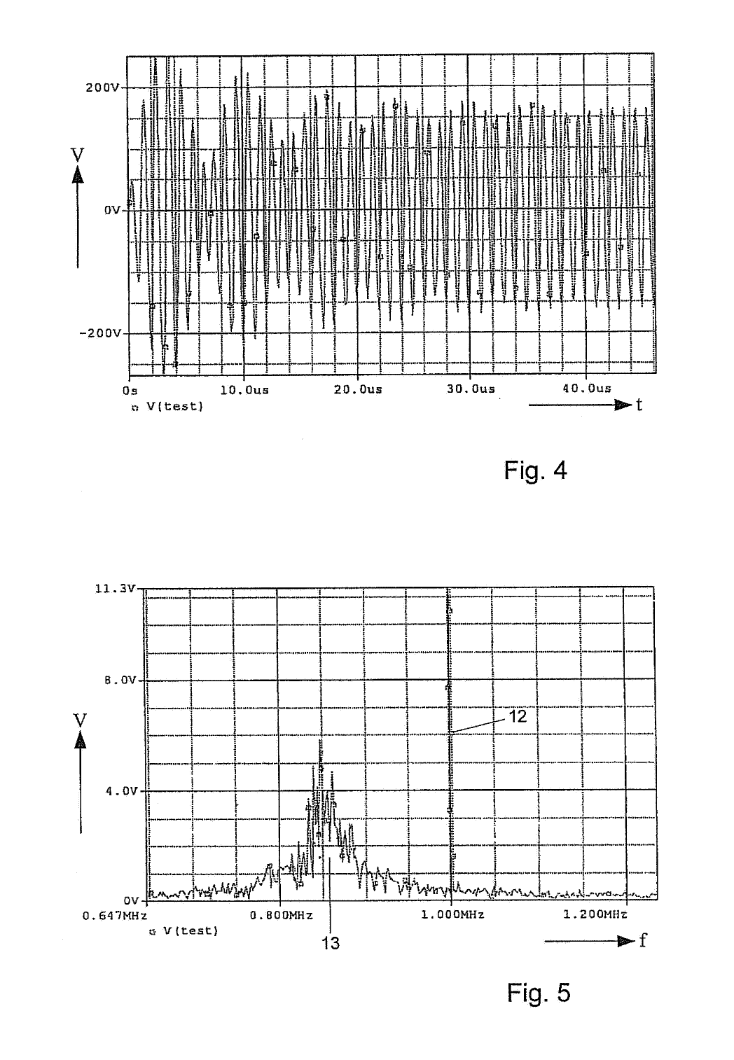

FIG. 4 shows a time domain diagram of signals that occur in the circuit of FIG. 3;

FIG. 5 shows an amplitude spectrum of the signals of FIG. 3;

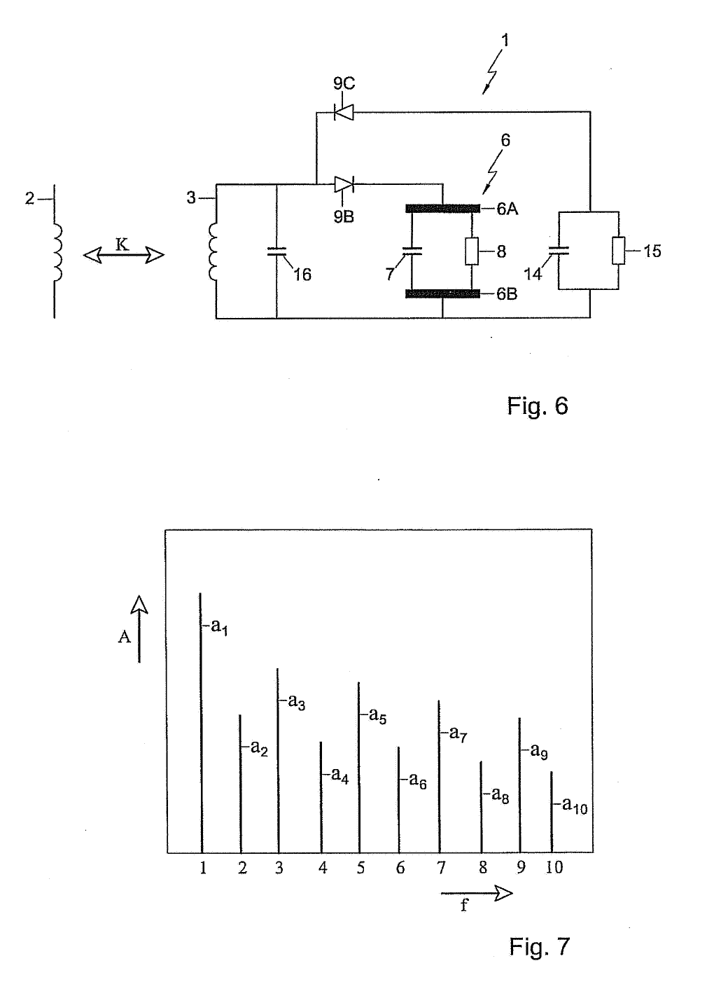

FIG. 6 shows a circuit of a fourth embodiment of an electrical measuring device according to the invention;

FIG. 7 shows an amplitude spectrum of a current through a coil;

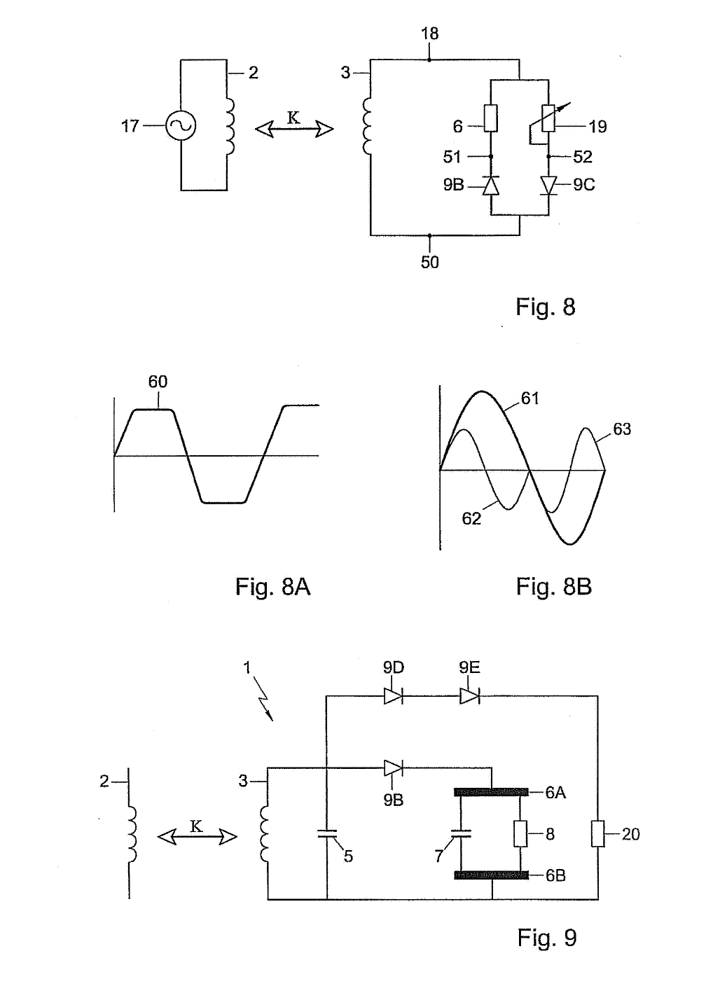

FIG. 8 shows a circuit of a fifth embodiment of an electrical measuring device according to the invention;

FIG. 8A shows a square wave signal;

FIG. 8B shows a fundamental harmonic and two second-order harmonics;

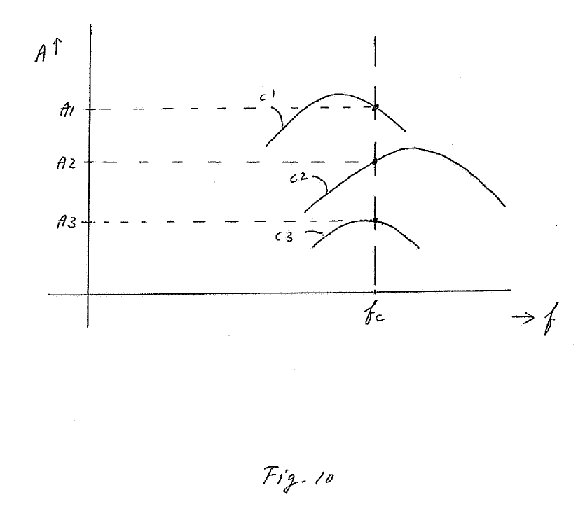

FIG. 9 shows a circuit of a sixth embodiment of an electrical measuring device according to the invention;

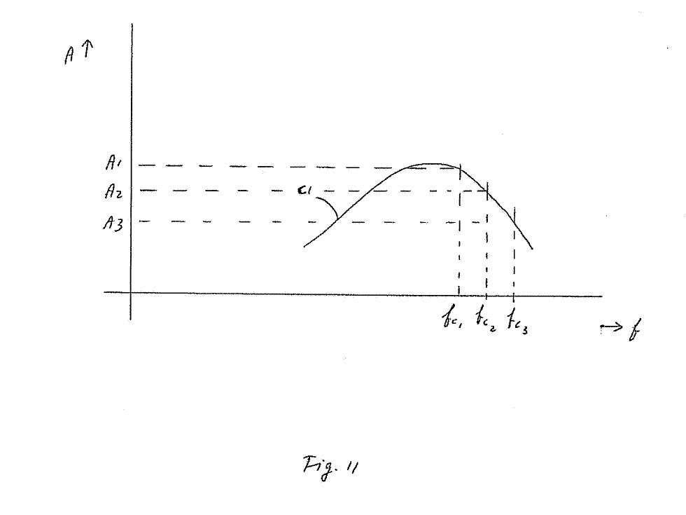

FIG. 10 shows a first amplitude spectrum of a signal generated by the measuring device;

FIG. 11 shows a second amplitude spectrum of a signal generated by the measuring device;

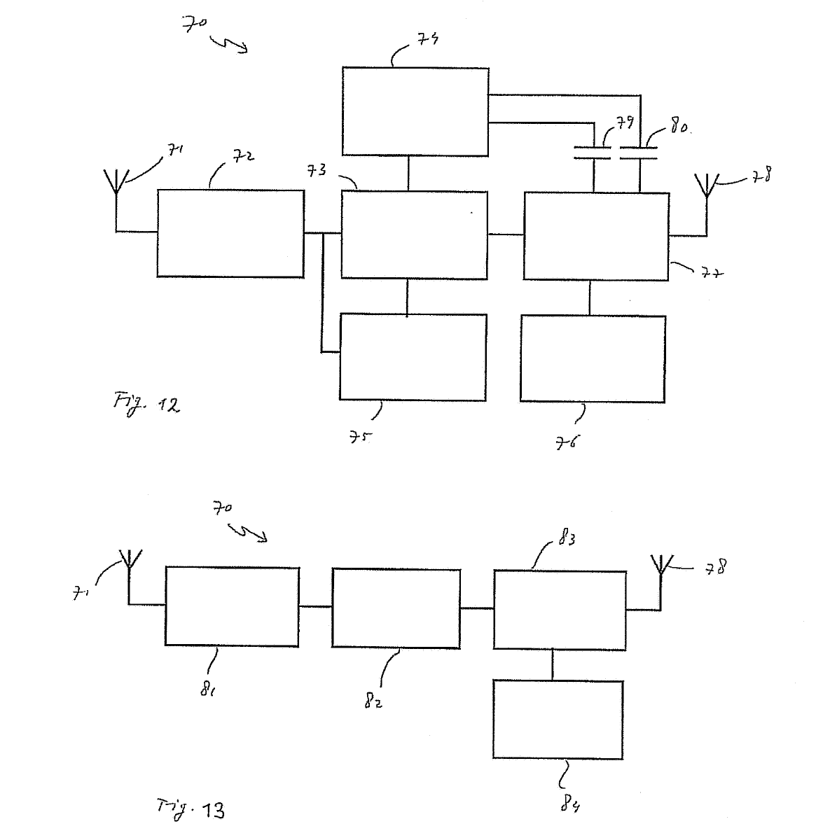

FIG. 12 shows a first schematic block diagram of a measuring unit; and

FIG. 13 shows a second schematic block diagram of a measuring unit.

The figures are only schematic representations of preferred embodiments of the invention. In the figures, equal or corresponding parts are designated by the same reference characters.

FIG. 1 shows a circuit 1 of a first embodiment of an electrical measuring device according to the invention.

The circuit 1 is arranged for performing a contactless impedance measurement. The circuit comprises two coils 2, 3 which are galvanically separated and during operation of the measuring device effect an electromagnetic coupling K. A first coil 2 is arranged in a separate active transmitting and receiving unit, the second coil 3 is part of a passive resonance circuit 4 in a measuring unit. Through the electromagnetic coupling, a mechanically speaking contactless measurement can be performed. It is noted that the electromagnetic coupling or radio connection may also be effected otherwise, for instance using electrical and/or magnetic dipoles.

As is apparent from FIG. 1, the resonance circuit 4 is passive, so that the measuring unit can be advantageously designed without batteries.

Connected in parallel to the coil 3 of the resonance circuit 4 are a reference capacitor 5 and an impedance 6 to be measured. The reference capacitor 5 is a possible implementation of an additional passive reference circuit. The impedance 6 to be measured between two impedance electrodes 6A, 6B is connectable via a switch 9 and has been modeled as a measuring capacitor 7 and measuring resistor 8 mutually connected in parallel, which, for instance, may typically have a value of about 100 pF and about 1,000Ω, respectively. The values can depend on the material to be measured, the surface of and the distance between the electrodes, as well as on the resonance frequency.

The operation of the measuring device is as follows. The coil 2 of the transmitting and receiving unit transmits an electromagnetic interrogation signal, for instance a radio wave having a frequency of 1 MHz, which is captured by the coil 3 of the resonance circuit 4, which is so tuned that a measuring signal or reference signal is generated, depending on the state of the switch 9. The measuring signal or reference signal is thereupon captured by the coil 2 of the transmitting and receiving unit, for analysis. By determining characteristics of the measuring signal or reference signal, such as spectral and/or amplitude information, information about electrical properties of the resonance circuit 4 can be determined. The impedance electrodes 6A, 6B can be placed in material to be examined, so that dielectric variations of the material between the impedance electrodes 6A, 6B can be determined. The other components of the resonance circuit 4 are accommodated in a casing, also referred to as package, for the purpose of durable use.

When the switch 9 is open, the resonance circuit is only formed by the coil 3 and the reference capacitor 5, so that a reference signal is obtained. In the closed state of the switch 9, the characteristics of the resonance circuit 4 are also formed by the impedance 6, so that a measuring signal is obtained. Thus, by the influence of the measuring capacitor 7 the peak frequency can be detuned and by the influence of the measuring resistor 8 the maximum spectral amplitude can diminish and/or spectral smearing can occur.

By operating the switching element 9 depending upon the interrogation signal and varying the frequency of the interrogation signal, for instance with a frequency shift, also referred to as frequency sweep, a detuned peak frequency can be detected.

The electrical measuring device according to the invention can be advantageously used for contactless measurement of local material characteristics, since the condition of material influences the electrical behavior of the impedance to be measured and hence the measuring signal that is generated by the resonance circuit. Changes in material relate for instance to moisture content, acidity and/or mineral concentration. Also, the electrical permittivity of for instance ceramics may be a measure for external moisture tension. Furthermore, a plastic layer provided on a substrate may be sensitive to ambient influences such as temperature, concentrations of gases or a pH value. Thus, the measuring device can for instance be implemented as a water content sensor for soil and/or substrate in which flowers, plants and/or other crops are rooted. The measuring device is then usuable for monitoring purposes, for instance in potted plants of growers or in agricultural lots. Optionally, the measuring device may be coupled to irrigation systems.

In additions, also other fields of application are conceivable, for instance in the field of bio-nanotechnology for observing changes in a biological substrate. Concrete examples of this are sensors for the food industry, such as sensor for checking milk quality, ageing of fruit juices and/or bacterial growth in meat products. Naturally, more applications are conceivable, for instance for determining the water content of a porous material, such as sand or cement, medical applications, water management and uses in the oil industry.

Thus, in practice, the measuring unit can be placed in the environment to be measured. The separate transmitting and receiving unit can be included in a mobile, optionally portable module and be carried along by a user. Thus, one and the same transmitting and receiving unit can be coupled contactlessly to a plurality of measuring units for the purpose of performing a contactless measurement. Consequently, savings on components in the measuring unit can be utilized still further.

Preferably, the parameters of the coil 3 and the reference capacitance 5 of the measuring unit are chosen such that a high quality factor is obtained. Furthermore, preferably, parameters of the components of the additional reference circuit are chosen such that a main frequency of the measuring signal and a main frequency of the reference signal differ mutually by about a few percents, so that requirements regarding bandwidth for equipment in the transmitting and receiving unit remain limited and secondary effects do not contribute significantly. In principle, however, parameters may also be chosen such that the main frequencies mentioned are further apart from each other. For the circuit as shown in FIG. 1, there is a quadratic relation between the ratio of the main frequencies on the one hand and the ratio of the capacitors on the other.

The switching element 9 in FIG. 1 is designed as a mechanical switch which can be operated via an external field. Thus, a reed relay, for instance, switches as a result of an external magnetic field. To that end, the separate transmitting and receiving unit may for instance be equipped with an actuator for generating the external magnetic field.

Preferably, an automatic amplitude control is used by the transmitting and receiving unit, so that the power loss resulting from the distance and matter between the transmitting and receiving unit and the measuring unit is corrected for.

FIG. 2 shows a circuit of a second embodiment of an electrical measuring device according to the invention, in which the switching element 9 is designed as a semiconductor switch, in particular a MOSFET 9A which is implemented via a rectifying circuit with a diode 10 and a capacitor 11. Upon an interrogation signal of a relatively low amplitude, the MOSFET 9A remains closed, so that a reference signal is generated. However, if an interrogation signal of a relatively high amplitude is received, the MOSFET 9A enters the conductive state, so that a measuring signal is generated. Naturally, also other semiconductor switches are possible. In addition, the circuit may be so arranged that upon an interrogation signal of a relatively low amplitude a measuring signal is generated, while upon an interrogation signal of a relatively high amplitude a reference signal is generated.

Furthermore, the switching element 9 may be designed as an electrical non-linear component, for instance a diode 9B, as shown in FIG. 3. As is the case with the above-described MOSFET 9A, the diode 9B enters the conductive state when the interrogation signal has an amplitude that is relatively high. During the switching on and off of a stationary interrogation signal, there occurs a switch-on and switch-off phenomenon, respectively, in which both the measuring signal and the reference signal are integrated.

For a proper operation of the resonance circuit, the diode 9B preferably has a low diode voltage, a high reverse voltage and a low junction capacitance.

FIGS. 4 and 5 show respectively a time domain and a spectral diagram of signals generated by the resonance circuit 4 in the circuit as shown in FIG. 3. The voltage V is plotted against time t and frequency f, respectively. The signals have a reference component 12 at the resonance frequency 1 MHz and a measuring component 13 around a shifted frequency near about 0.85 MHz. The measuring component 13 has a certain spectral width caused by measuring resistance 8.

FIG. 6 shows a circuit of a fourth embodiment of an electrical measuring device according to the invention. Here, the switching element 9 is designed as a circuit of two diodes 9B, 9C which are respectively connected to the impedance 6 to be measured and an additional passive reference circuit. Connected parallel to the coil 3 of the measuring unit is a resonance capacitor 16 for obtaining a resonance circuit 4. The additional passive reference circuit, also called reference impedance, comprises a reference capacitor 14 and a reference resistor 15 mutually connected in parallel. Naturally, the additional passive reference circuit may also be designed differently, for instance as only the capacitor 14 or the resistor 15 or in combination with an additional coil.

Through the structure of the circuit, the positive part of a harmonic interrogation signal is presented to the impedance 6 to be measured, while the negative part is presented to the reference impedance 14, 15. Moreover, higher harmonics of the interrogation signal arise. The amplitude and phase of the higher harmonics contain information about the impedance 6 to be measured and the reference impedance 14, 15. In the specific case where the measuring and reference impedance 7, 8; 14, 15 are equal, the even harmonics quench. Also in other situations of the reference and measuring impedance 14, 15; 6, the parameters of the measuring impedance 6 can be determined on the basis of the information about the harmonics. Here, use can be made of both amplitude and phase information of various spectral components.

FIG. 7 shows an amplitude spectrum of the electrical current through the second coil 3, which is explained as follows. The sine-shaped current through each diode branch separately causes even harmonics because of the non-linearity of the diode. Because one diode is conductive during the positive part of the sine and the other during the negative part, the even harmonics in the two diode branches, as illustrated in FIG. 8, cancel out, while electrical quantities such as a square wave 60, a fundamental harmonic 61 and two second-order harmonics 62, 63 are shown with respect to respective terminals 18, 18, 51, 52 of the second coil 3 and the diodes 9B, 9C in FIGS. 8A and 8B. When the impedances 6, 19 in the diode branches are equal to each other, the current through the second coil 3 is therefore built up only from odd harmonics of an original square wave 60 induced by the first coil 2. When the impedances 6, 19 differ, the even harmonics in the two diode branches are not equal anymore leaving a differential current in the second coil 3. Consequently, the current through the second coil 3 comprises both even and odd harmonics. The amplitude spectrum may then for instance look as shown in FIG. 7, where the amplitude A of the harmonics a1, . . . , a10 is shown as a function of a normalized frequency f. Generally, the amplitude of the even harmonics is a function of the inequalities of the impedances 6, 17 and the amplitude of the original square wave 60. For that reason, from the amplitude of the received signal, the inequality in the two impedances can be derived. The amplitude of the odd harmonics is virtually exclusively a function of the square wave 60.

Phase information can for instance be obtained by generating higher harmonics locally at the transmitting and receiving unit and applying synchronous detection to determine the phase relation with the spectrum components of the signal generated by the resonance circuit. A synchronous detector has the advantage of a very high dynamic range and a low interference sensitivity.

To realize a constant operation point for the diodes, the amplitude of the first harmonic may be so controlled that the amplitude of one of the transmitted odd harmonics remains in a fixed ratio to the amplitude of the first harmonic, regardless of the distance between the two coils 2, 3. The amplitude ratio between the even and odd harmonics is then uniformly fixed and is an absolute measure for the inequality between the impedances.

The inequality in the two branches can also be realized by applying an extra voltage or current across or through the two impedances, for instance by using diodes with different base emitter voltages. Thus, the even harmonic can be modulated with another signal which contains for instance an identification code.

FIG. 9 shows a circuit of a sixth embodiment of an electrical measuring device according to the invention, where the circuit from FIG. 3 has been expanded to include an extra subcircuit which is connected parallel to the second coil 3. The extra subcircuit is a series connection of two diodes 9D, 9E and an extra impedance 20. By raising the amplitude of the interrogation signal still further, also the extra subcircuit can be rendered conductive, so that in response to the interrogation signal yet another signal is transmitted, differing from the measuring signal and reference signal, since also the extra impedance 20 has in fact been additionally connected. As a consequence, an extra measurement can be performed, for instance of the temperature. Thus, setting of the amplitude level of the interrogation signal allows selecting between different types of response signals, thus allowing a coded interrogation of the measuring unit. More generally, the measuring unit is provided with an extra circuit for, depending upon the interrogation signal, generating an extra signal to be wirelessly received by the active transmitting and receiving unit.

If desired, the pattern of the extra subcircuits may be further continued with a parallel circuit in which three or more diodes are series-connected. Furthermore, such an extra subcircuit may also be used in combination with other embodiments of the invention, for instance as shown in FIGS. 2 and 6.

The transmitting and receiving unit is preferably provided with a processor for processing the measuring and reference signal to determine the electrical impedance.

The method for carrying out such processing operations can be practiced both with the aid of specific processor components and with the aid of specific program.

Optionally, calculations of the reference signal may performed on one or more defined harmonics and calculations of the measuring signal on the basis of one or more other harmonics.

According to an aspect of the invention, signals are processed by the separate transmitting and receiving unit for determination of the electrical impedance. This can be executed in different ways.

In a first embodiment, during a single or multiple reference measurement an impedance connected to the resonance circuit can vary by switching one or more reference circuits on or off using one or more switches. As a result, obviously, the amplitude characteristic of the resonance circuit changes. This characteristic changing per measurement is measured at a fixed frequency. In principle, however, it is also possible to choose any random other frequency in consecutive measurements. In addition, a peak frequency of the amplitude characteristic changing per measurement may be determined. In this first embodiment, the amplitude characteristic can, as it were, shift as a function of the frequency.

In a practical embodiment according to the invention, in case of a plurality of received signals at a fixed, predetermined frequency a normalized amplitude of the integral resonance circuit impedance can be determined. FIG. 10 shows a first amplitude spectrum A with three amplitude characteristics c1, c2, c3 as a function of the frequency f, that correspond with a measuring signal and two reference signals which have been generated by the measuring unit. At a fixed frequency f_{c}, the corresponding normalized amplitudes A1, A2, A3 of the integral resonance circuit impedance are determined. The frequency-dependent integral resonance circuit impedance can be modeled on the basis of three parameters, viz. a resistivity or conductivity, a capacitance and an inductivity. Furthermore, a normalization is done through multiplication of the resonance circuit impedance by a scalar transfer function of the transfer between the measuring unit and the separate transmitting and receiving unit. On the assumption that the scalar transfer function is invariant during the various measuring signals and that the other three parameters that characterize the resonance circuit impedance are also constant or vary in a controlled manner through operation of switches, a set of equations may be drawn up from which the three parameters and the scalar transfer function may be resolved. From this, the impedance to be measured can then be determined. On the assumption that the inductivity is sufficiently known, three measurements are then sufficient to determine the three other parameters, viz. the scalar transfer function, the conductivity and the capacity.

In this context, it is noted that the accuracy of the measurement as a whole can be improved by predetermining the inductivity more accurately, for instance by calibration or trimming of the inductivity. Furthermore, other parameters, such as the conductivity and/or the capacity may be determined better, for instance by a measurement in the air. Furthermore, a reference capacity may be additionally included in the circuit to obtain a better estimate of the inductivity through a reference measurement.

It is noted that instead of three measurements, also a different number of measurements may be performed for determining the impedance, for instance two measurements where through extrapolation an estimate of the third unknown parameter can be obtained, or more than three measurements, for instance four measurements, so that the accuracy of the measurement can be improved, for instance using a least square method.

In a second embodiment for processing signals, the measuring unit is arranged, depending upon the interrogation signal, to generate with the aid of the resonance circuit a reference signal having a central frequency that differs from the central frequency of the measuring signal. Thus, the value of the electrical impedance to be measured can be determined by determining the amplitude characteristic of the normalized resonance impedance at different frequencies. FIG. 11 shows a second amplitude spectrum A with a single amplitude characteristic c1 as a function of the frequency f which corresponds to a measuring signal and two reference signals generated by the measuring unit. By determining the amplitudes A2, A2, A3 at different frequencies fc1, fc2, fc3, the value of the electrical impedance can be derived on the basis of the above-mentioned modeling. By choosing the different frequencies at which the amplitude spectrum is measured at a relatively steep slope of the amplitude spectrum, the resolution of the measurement can be increased.

According to another aspect of the invention, the interrogation signal can be transmitted at a first frequency, for instance about 27 MHz, while the measuring signal and/or the reference signal is determined at a different, second frequency. To this end, the measuring unit may be arranged to transmit the measuring signal at the second frequency, for instance about 13.5 MHz. It is also possible for the measuring unit to transmit a measuring signal whose energy is substantially concentrated around the first frequency, while the receiving unit measures the measuring signal at the second frequency. By using different frequencies for the transmitted signal and return signal, interference, for instance due to inductance of the transmitter unit, be can controlled. Also, the effect of higher harmonics can be controlled.

FIG. 12 shows a diagrammatic block diagram of a measuring unit according to the above-outlined principle. The measuring unit 70 comprises a receiver 71 which passes a received signal on to a receiver circuit 72, connected thereto, which is tuned to a first frequency, in this case for instance about 27 MHz. Further, the unit 70 comprises a frequency divider 73 which is supplied by a supply unit 75 which is provided with energy by the receiver circuit. Furthermore, the frequency divider 73 is connected to a multiple frequency divider 74 and to a resonance circuit 77 which in turn is connected to measuring electrodes 76. The multiple frequency divider 74 functions to successively link up a first and a second reference circuit 79, 80, each comprising a known reference capacity. As a result, in each case a sequence of the measuring signal and two reference signals is transmitted by the measuring unit 70. The measuring signal and the two reference signals are all directed via the resonance circuit 77 to a transmitter 78 connected thereto, in order to be transmitted, so that the separate transmitting and receiving unit can received and process these signals. The resonance circuit 77 is tuned to 13.5 MHz. In this embodiment of the measuring unit, the frequency of the signals hence remains constant while the impedance connected to the resonance circuit alters.

According to another aspect of the invention, the interrogation signal comprises a modulated signal, for instance a primary signal at for instance about 27 MHz which, through amplitude modulation, has been modulated on a carrier of for instance 2.4 GHz. The modulated signal can be demodulated on the measuring unit, for instance with a diode circuit, so that the measuring unit in response thereto can transmit a measuring signal and/or a reference signal.

FIG. 13 shows a schematic block diagram of a measuring unit according to the above-outlined principle. The measuring unit 70 comprises a receiver 71 which passes a received signal on to a receiver circuit 81, connected thereto, which is tuned to a first frequency, in this case for instance about 2.4 GHz. The thus filtered signal is passed on to an amplitude modulation detector, for instance designed as a diode, for extracting the baseband signal, for instance a signal of approximately 27 MHz. This signal, depending upon the measuring impedance that is connected to the measuring electrodes, is transmitted via a transmitter 78 for reception by the separate transmitting and receiving unit. Instead of a signal of 27 MHz, naturally also a slightly altered signal may be used, for instance 26.9 MHz or 27.1 MHz. By successively using signals with slightly altered frequencies, thus a scheme may be used whereby the characteristics of the impedance connected to the resonance remain unchanged, while extra information is gained by determining the amplitude spectrum at different frequencies.

It is noted that the electrical measuring device comprises only a single resonance circuit, so that only a relatively small number of components are required. Moreover, the measuring unit is relatively compact. In addition, a narrow-band measurement is carried out, so that in practice the measurement can be carried out reliably within a small bandwidth. The invention is not limited to the exemplary embodiment described here. Many variations are possible.

Thus, the additional passive reference circuit may be implemented differently, for instance to additionally comprise a reference resistance or to comprise only a reference resistance.

Furthermore, an electrical nonlinear component serving as the switching element may be designed not only as a diode but also as a thyristor, triac, gas discharge tube, polymer ESD protection element, or a nonlinear resistance.

Furthermore, it is noted that in the embodiment as shown in FIG. 1 the additional passive reference circuit and the impedance to be measured may in principle be interchanged.

Also, instead of a resonance circuit based on a parallel-connected coil and capacitor(s), a different resonance circuit may be used, for instance using two or more coils.

In addition, it is noted that the measuring signal and the reference signal may be received by the same receiver unit or by separate receiver units.

According to an aspect of the invention, the communication between the separate active transmitting and receiving unit on the one hand and the measuring unit on the other hand may also take place via a wire connection. To this end, the separate active transmitting and receiving unit may for the purpose of performing a measurement for instance be coupled to the measuring unit with a detachable connecting module.

Furthermore, the measuring device may be provided with a series circuit in order to compensate for transmission line effects that are caused by electrodes in wet substrate. Alternatively, however, such compensation may also be carried out afterwards by means of computer calculations.

Furthermore, one or more reference circuits may be linked up or cut off using one or more circuits, so that the measuring device is suitable for a measurement on an impedance with a relatively large amplitude range.

In addition, it is noted that through antiparallel connection of diodes functioning as switching element, no DC voltage across the diodes can be built up that might hamper the operation of the diode.

Such variants will be clear to those skilled in the art and are understood to be within the scope of the invention as set forth in the following claims.

1. An electrical measuring device for performing an electrical impedance measurement, comprising a measuring unit which is provided with the impedance to be measured and a passive resonance circuit connected thereto for generating a measuring signal to be received by a separate active transmitting and receiving unit for determination of the electrical impedance, upon reception of an interrogation signal transmitted by the active transmitting and receiving unit, wherein the measuring unit is furthermore arranged for, depending upon the interrogation signal, generating with the aid of the resonance circuit a reference signal to be received by the active transmitting and receiving unit.

2. The electrical measuring device according to claim 1, wherein the signals transmitted by the measuring unit are narrow-band.

3. The electrical measuring device according to claim 1, wherein the measuring unit is arranged for, depending upon the interrogation signal, generating with the aid of the resonance circuit a specific reference signal from a plurality of reference signals.

4. The electrical measuring device according to claim 1, wherein the measuring unit and the separate active transmitting and receiving unit are arranged for wireless mutual signal transfer.

5. The electrical measuring device according to claim 1, furthermore comprising a reference circuit for, depending upon the interrogation signal, generating with the aid of the resonance circuit a reference signal.

6. The electrical measuring device according to claim 1, wherein the measuring unit is arranged for, depending upon the interrogation signal, generating with the aid of the resonance circuit a reference signal having a central frequency that differs from the central frequency of the measuring signal.

7. The electrical measuring device according to claim 1, wherein the reference circuit is connected to the resonance circuit.

8. The electrical measuring device according to claim 1, wherein the impedance to be measured or the additional reference circuit is connected to the resonance circuit via a switching element.

9. The electrical measuring device according to claim 1, wherein the switching element is designed as a mechanical switch operable via an external field or as a semiconductor switch.

10. The electrical measuring device according to claim 1, wherein the switching element is designed as an electrical nonlinear component.

11. The electrical measuring device according to claim 1, wherein the additional reference circuit is placed in a space that is at least partially conditioned.

12. The electrical measuring device according to claim 1, wherein the additional reference circuit comprises a reference capacity which is part of the resonance circuit.

13. The electrical measuring device according to claim 1, wherein both the impedance to be measured and the additional reference circuit are connected to the resonance circuit via a switching element.

14. The electrical measuring device according to claim 1, wherein the additional reference circuit comprises a reference capacity and reference resistance mutually connected in parallel.

15. The electrical measuring device according to claim 1, wherein parameters of the components of the additional passive reference circuit are chosen such that a main frequency of the measuring signal and a main frequency of the reference signal mutually differ by about a few percents.

16. The electrical measuring device according to claim 1, furthermore comprising the active transmitting and receiving unit.

17. The electrical measuring device according to claim 1, wherein the active transmitting and receiving unit comprises a processor for processing the measuring signal and the reference signal for determination of the electrical impedance.

18. The electrical measuring device according to claim 1, wherein the measuring signal and the reference signal comprise one or more components of harmonics which are generated by the electrical nonlinear component.

19. The electrical measuring device according to claim 1, wherein the measuring unit is furthermore provided with an extra circuit for, depending upon the interrogation signal, generating an extra signal to be wirelessly received by the active transmitting and receiving unit.

20. The electrical measuring device according to claim 1, wherein the additional reference circuit is of passive design.

21. A method for performing an electrical impedance measurement, comprising the steps of
transmitting an interrogation signal with the aid of an active transmitting and receiving unit;
upon reception of the interrogation signal, generating a measuring signal by means of a passive resonance circuit of a separate measuring unit, which resonance circuit is connected to the impedance to be measured;
receiving the measuring signal with the aid of the active transmitting and receiving unit for determination of the electrical impedance; and
performing a reference measurement on the measuring unit, the reference measurement being performed by, depending upon the interrogation signal, generating via an additional circuit and the resonance circuit a reference signal to be received by the active transmitting and receiving unit.

22. A computer program product which is readable by a processing unit for causing a reference measurement to be performed on a measuring unit forming part of a measuring device for performing an electrical impedance measurement, which measuring unit is provided with an electrical impedance to be measured and a passive resonance circuit connected thereto, wherein the reference measurement is performed in that a measuring signal to be received by a separate active transmitting and receiving unit, which upon reception of an interrogation signal transmitted by the active transmitting and receiving unit is generated by the resonance circuit, and a reference signal to be received by the active transmitting and receiving unit, which, depending upon the interrogation signal to be transmitted by the separate transmitting and receiving unit, is generated with the aid of an additional circuit and the resonance circuit, are processed for determination of the electrical impedance.
